(19) United States
(12) Patent Application Publication
(10) Pub. No.: US 2026/0275573 A1
(43) Pub. Date: Sep. 17, 2026

(54) METHOD FOR SLICING CRYSTAL MATERIAL, METHOD FOR MANUFACTURING WAFER, AND MEMBER COMPRISING CRYSTAL MATERIAL

(71) Applicants: National University Corporation Chiba University, Chiba (JP); Orbray Co., Ltd., Tokyo (JP)

(72) Inventors: Hirofumi HIDAI, Chiba (JP); Kosuke SAKAMOTO, Chiba (JP); Daijiro TOKUNAGA, Chiba (JP); Souta MATSUSAKA, Chiba (JP); Sho ITO, Chiba (JP); Koji KOYAMA, Tokyo (JP); Seongwoo KIM, Toyko (JP)

(21) Appl. No.: 19/162,720

(22) PCT Filed: Mar. 22, 2024
(86) PCT No.: PCT/JP2024/011511

§ 371 Date: Sep. 5, 2025

(30) Foreign Application Priority Data
Mar. 22, 2023 (JP) 2023-045708

(51) Int. Cl. C30B 33/04; C30B 29/04; H10D 62/40; H10D 62/83; H10P 54/30; H10P 54/50

(52) U.S. Cl. CPC C30B 33/04; C30B 29/04; H10D 62/405; H10D 62/8303; H10P 54/30; H10P 54/52

(57) ABSTRACT

A planar modified layer 3 including a first modified portion 2 is formed in a material 1 made of a crystal material at a plurality of places on the same plane at intervals, and subsequently, a second modified portion 7 is formed between the adjacent modified layers 3. Cracks generated in the adjacent modified layers 3 are joined by forming the second modified portion 7, and a thin plate 9 is peeled off from the material 1. The thin plate having a large area can be peeled off from the crystal material.

### TECHNICAL FIELD

The present invention relates to a method for slicing a crystal material, a method for manufacturing a wafer, and a member including a crystal material.

### BACKGROUND ART

When manufacturing a substrate of a semiconductor device such as an IC or an LSI, it is necessary to slice a wafer from an ingot of a single crystal material. In slicing, it has been common to use a wire saw. In recent years, as wafers, the use of hard single crystal materials, such as silicon carbide (SiC), gallium nitride (GaN), sapphire, and diamond, which are excellent in thermal conductivity, chemical resistance, mechanical properties, and the like, has been studied. However, these single crystal materials are hard, and therefore slicing with a wire saw is difficult.

As a method for slicing such a hard single crystal material, a method of forming a modified layer and a crack on a surface to be cut by irradiating a single crystal material with a laser beam having a wavelength transmissive to the single crystal material with a light condensing point positioned inside an ingot, cleaving along the surface to be cut on which the modified layer and the crack are formed by applying an external force, and separating a wafer from the ingot is proposed in Patent Literature 1 below. A similar slicing method is described in Non-Patent Literature 1 below.

### CITATIONS LIST

### Patent Literature

Patent Literature 1: JP 2016-111145 A

### NON-PATENT LITERATURE

Non-Patent Literature 1: Akihito Ono and three others, “Study on Laser Slicing Technology of Diamond-Observation of the Internal Damage”, Proceedings of 2017 JSPE Spring Conference, p. 429-430

### SUMMARY OF INVENTION

### Technical Problems

In the single crystal material, there is a plane (cleavage plane) that is easily peeled off, and a direction of the cleavage plane is also determined depending on a direction of the crystal. For example, in diamond, a (111) plane is a cleavage plane, but the (111) plane is inclined at about 55° with respect to a (100) plane. As described above, in diamond, the direction of the cleavage plane with respect to the crystal plane is greatly different, and therefore even if cleavage is attempted on the (100) plane, the cleavage direction is often bent in the direction to become the (111) plane.

When diamond is used as a wafer, a commonly used surface is the (100) plane. When cleavage of diamond along the (100) plane is attempted by applying a method described in Patent Literature 1, a crack can be extended along the (100) plane and peeling can be performed along the (100) plane if the modified layer has a small area with one side of up to about 100 μm. However, since volume expansion occurs in the modified layer due to graphitization, if the modified layer having a larger area is formed, the crack extends to a region away from the modified layer. When the crack extends at a certain distance from the modified layer, a crack propagation direction bends from a direction parallel to the modified layer, and crack extension starts in a cleavage plane direction, so that cleavage along the (100) plane parallel to the modified layer becomes difficult.

In the method described in Non-Patent Literature 1, a dot pitch, a line pitch, and the like are precisely controlled in order to prevent a large crack. Therefore, it is necessary to use high-precision and expensive equipment in order to process a narrow window with high reproducibility. In addition, when a wafer is changed, it is necessary to review irradiation conditions of a laser beam, which requires complicated labor. Therefore, it is desired to provide a slicing method that has a wide window and widens options of materials and devices.

When the wafer is used as a substrate material of a semiconductor device, an inch size wafer is required, but in the methods of Patent Literature 1 and Non-Patent Literature 1, it is difficult to obtain a diamond wafer having a required size for the above reason.

Therefore, an object of the present invention is to provide a method for slicing a crystal material capable of peeling a thin plate having a large area from the crystal material.

### Solutions to Problems

In order to achieve the above object, a method for slicing a crystal material according to the present invention includes: forming a planar modified layer including a first modified portion in a material made of a crystal material at a plurality of places on a same plane at intervals, the crystal material having cleavability; subsequently forming a second modified portion between the modified layers adjacent to each other; and joining cracks generated in the adjacent modified layers by forming the second modified portion, and peeling a plate (thin plate) from the material.

According to the above method, it is possible to avoid unintended extension of a crack due to slicing (for example, extension of a crack in a cleavage plane direction). Therefore, the thin plate having a large area can be peeled off from the material.

In order to obtain such an effect, it is preferable that the modified layer before forming the second modified portion has a size in which a crack in a cleavage plane direction does not extend.

In addition, the interval between the adjacent modified layers before forming the second modified portion is preferably set to a size in which cracks generated in the modified layers are not joined to each other.

In the slicing method described above, the crystal material may be diamond, and the first modified portion and the second modified portion may have a graphitized structure. A crack existing region is formed around the first modified portion due to volume expansion accompanying graphitization. By providing the second modified portion between the adjacent modified layers, the cracks in the crack existing regions of the adjacent modified layers are joined to each other, so that the thin plate can be peeled off from the material.

By using diamond as the crystal material and arranging the modified layers formed at the plurality of places on the same plane parallel to a (100) plane, it is possible to peel the thin plate along a (100) plane direction.

The first modified portion of the modified layer can be formed at a position aligned in each of a row direction and a column direction of the modified layer. As a result, since the intervals between the first modified portions become equal, cracks generated around the first modified portions in the modified layer can be stably joined.

By providing, as the first modified portion of the modified layer, a main modified portion formed at a position aligned in each of a row direction and a column direction of the modified layer and a sub-modified portion located between the main modified portions adjacent in the row direction and between the main modified portions adjacent in the column direction, the modified layer having a larger area can be formed, and the thin plate having a large area can be efficiently sliced form the material.

By slicing the material by the method described above, it is possible to form a wafer having a large diameter.

In addition, in a member including a crystal material according to the present invention, a planar modified layer including a first modified portion is formed in a material made of a crystal material at a plurality of places on the same plane at intervals, and the crystal material has cleavability, and a second modified portion is formed between the modified layers adjacent to each other.

By performing a post-process such as applying an external force to the member made of such a crystal material, the thin plate can be separated from the material using the plane including all the modified layers as an interface.

### Advantageous Effects of Invention

As described above, according to the present invention, it is possible to stably peel the thin plate having a large area from the crystal material.

### BRIEF DESCRIPTION OF DRAWINGS

FIG. 1 is a cross-sectional view illustrating an outline of a first modified portion formed inside a material in a direction orthogonal to a (100) plane.

FIG. 2 is a cross-sectional view illustrating an outline of a modified layer formed inside the material in the direction orthogonal to the (100) plane.

FIG. 3 is a cross-sectional view taken along a line A-A in FIG. 2.

FIG. 4 is a cross-sectional view taken along the line A-A in FIG. 2, illustrating the modified layers formed at a plurality of locations.

FIG. 5 is a cross-sectional view taken along the line A-A in FIG. 2, illustrating the material provided with a second modified portion.

FIG. 6 is a cross-sectional view illustrating a stress distribution in a state of FIG. 4 in the direction orthogonal to the (100) plane.

FIG. 7 is a cross-sectional view illustrating a stress distribution in a state of FIG. 5 in the direction orthogonal to the (100) plane.

FIG. 8 is a cross-sectional view illustrating a step of peeling a thin plate from the material in the direction orthogonal to the (100) plane.

FIG. 9 is a cross-sectional view taken along the line A-A in FIG. 2, illustrating another arrangement pattern of the first modified portion.

### DESCRIPTION OF EMBODIMENT

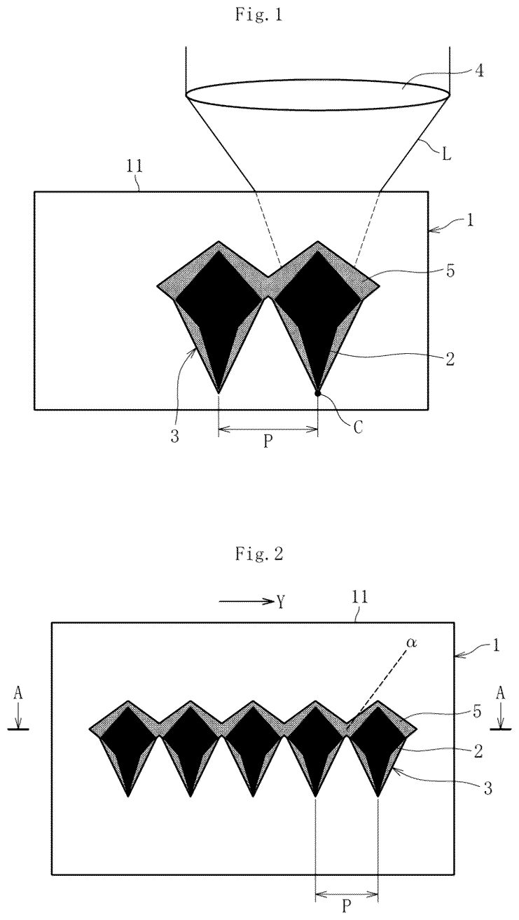

Hereinafter, an embodiment of a method for slicing a crystal material according to the present invention will be described with reference to FIGS. 1 to 9.

In the present embodiment, a crystal material to be sliced is a single crystal or polycrystal material having cleavability. In many cases, the single crystal material has cleavability. A so-called highly oriented polycrystal material in which directions of crystal grains are aligned even in the polycrystal material has cleavability, and thus can be included in the object of slicing according to the present embodiment. In addition, a material that can be regarded as a substantially single crystal and is produced by heteroepitaxial growth in which diamond is grown on a substrate of a dissimilar material is also included in the “single crystal material”. In the following description, the slicing method will be described by taking diamond as an example of the single crystal material. Single-crystal diamond has useful physical properties such as high hardness, high thermal conductivity, a wide light transmission wavelength band and a band gap, a low dielectric constant, and excellent chemical stability, and therefore the single-crystal diamond is regarded as promising as a substrate for a next-generation semiconductor device or a material for a high-precision magnetic sensor.

The slicing method according to the present embodiment includes: (1) a modified layer forming step of forming a planar modified layer at a plurality of places inside a material (ingot or block); (2) a crack joining step of joining cracks of the respective modified layers formed in the modified layer forming step; and (3) a peeling step of peeling a thin plate from the material 1 subjected to the crack joining step. Slicing of the material 1 made of diamond is performed through the steps in the order of (1) to (3). Hereinafter, details of the steps will be described.

### Modified Layer Forming Step

As shown in FIG. 1, the modified layer forming step is a step of forming a planar modified layer 3 including a large number of dot-shaped first modified portions 2 inside a material 1 formed of a single crystal material.

The material 1 made of diamond is manufactured by a high-temperature and high-pressure (HTPT) method, a chemical vapor deposition (CVD) method, or the like. Examples of the diamond include type Ia, type IIa, and type IIb, and any type of diamond can be used. A surface 11 of the material 1 is polished to be flat and extends in a direction parallel to a (100) plane.

As illustrated in FIG. 1, the first modified portion 2 is formed by irradiating the surface 11 of the material 1 with a laser beam L having a wavelength that passes through the material 1 and condensing the laser beam L from the surface 11 into the material 1 at a predetermined depth using an objective lens 4. In the first modified portion 2, a diamond structure is graphitized by thermal decomposition. The first modified portion 2 is formed so as to extend from a light condensing portion C in an optical axis direction, and has a length of about 10 μm to 50 μm in the optical axis direction.

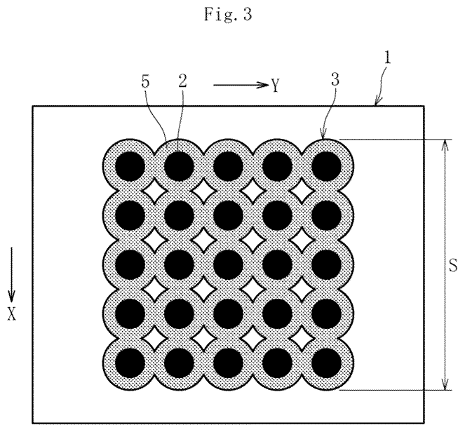

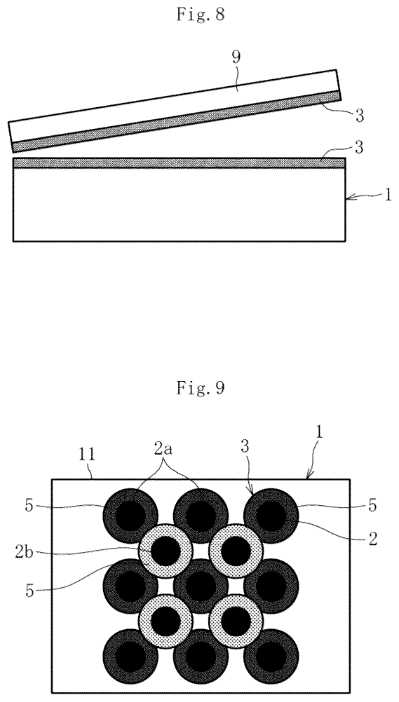

As shown in FIG. 2, the first modified portion 2 is formed at a plurality of places inside the material 1 at a predetermined pitch P. Each of the first modified portions 2 is formed by condensing the laser beam at the same depth from the surface 11. Therefore, each of the first modified portions 2 is located on the same plane parallel to the (100) plane. A position of the light condensing portion C is determined according to thickness of a thin plate 9 (see FIG. 8) to be obtained, and for example, when the position of the light condensing portion C is deepened, the thickness of the thin plate 9 can be increased. The light condensing portion C can be set to a depth of 50 μm to 700 μm from the surface 11, for example.

The laser beam is emitted from a laser beam source (not illustrated) with, for example, a picosecond pulse. Pulse width (pulse duration) can be selected in a range of several ps to several hundred ps.

In the first modified portion 2, since volume expansion occurs due to the graphitization, cracks occur in the periphery by a wedge effect due to the volume expansion. FIGS. 1 and 2 are diagrams conceptually showing a peripheral structure of the first modified portion 2, where a black coated portion represents the graphitized first modified portion 2, and a gray color portion around the first modified portion 2 represents a region 5 at which a crack generated by the volume expansion of the first modified portion 2 exists (hereinafter, referred to as a “crack existing region”). As illustrated in FIG. 1, the pitch P between the adjacent first modified portions 2 is set to a size at which the crack existing regions 5 are connected to each other in a (100) plane direction. For example, by setting the pitch P to about 10 μm to 30 μm, the crack existing regions 5 of the adjacent first modified portions 2 can be connected to each other.

As illustrated in FIGS. 2 and 3, the planar modified layer 3 extending in the (100) plane direction is formed by the first modified portion 2 and the crack existing region 5 around the first modified portion 2. The term “planar” as used herein means that the modified layer 3 looks planar when viewed from a naked eye level. For example, as illustrated in FIG. 3, the modified layer 3 is formed by repeating a procedure in which a pulsed laser is scanned in an X direction along the surface 11 of the material 1, and then the pulsed laser is scanned again in the X direction at a position shifted in a Y direction (direction orthogonal to the X direction) along the surface 11. As a result, the first modified portions 2 are formed in a state of being aligned at a plurality of positions in each of a row direction (X direction) and a column direction (Y direction).

As illustrated in FIG. 3, the first modified portions 2 adjacent in the X direction and the Y direction are in a state in which the crack existing regions 5 are connected to each other. It is not always necessary that the crack existing region 5 of any one of the first modified portions 2 is connected to all the peripheral crack existing regions 5, and it is sufficient that the crack existing region 5 is connected to at least one of the peripheral crack existing regions 5. In addition, there is no particular problem even if a small number of independent crack existing regions 5 not connected to any peripheral crack existing region 5 are formed in the modified layer 3.

As described above, when an area of the modified layer 3 is too large, a crack naturally extends even in a state where no external force is applied to the material 1 due to accumulation of stress by volume expansion. Therefore, a crack occurs even in a portion away from the modified layer 3, and a crack a (hereinafter, referred to as an “antiplane crack”) in a cleavage plane direction (direction of a (111) plane) occurs as indicated by a broken line in FIG. 2. When the crack a in the cleavage plane direction occurs as described above, it is difficult to peel the thin plate along the (100) plane.

Therefore, the area of the modified layer 3 is preferably as large as possible within a range in which the crack α in the cleavage plane direction does not extend. For example, if the modified layer 3 has a square outline in which one side S is about 50 μm to 100 μm when viewed from the surface 11 side, it is possible to avoid occurrence of such a crack a in the cleavage plane direction. A shape of the modified layer 3 may be other shapes such as a rectangle and a circle in addition to the square.

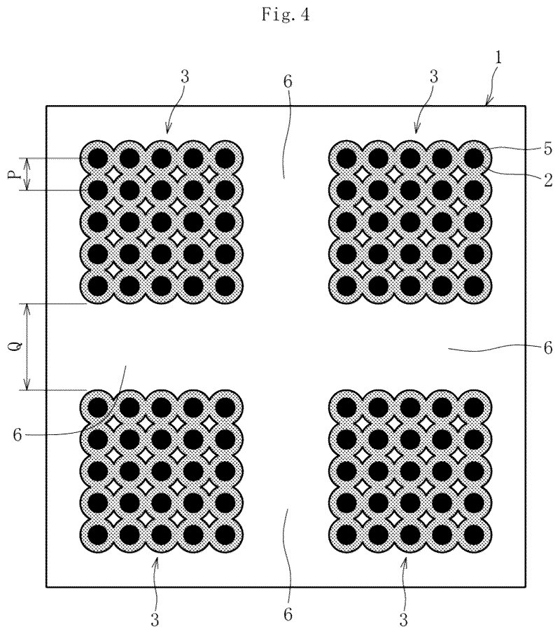

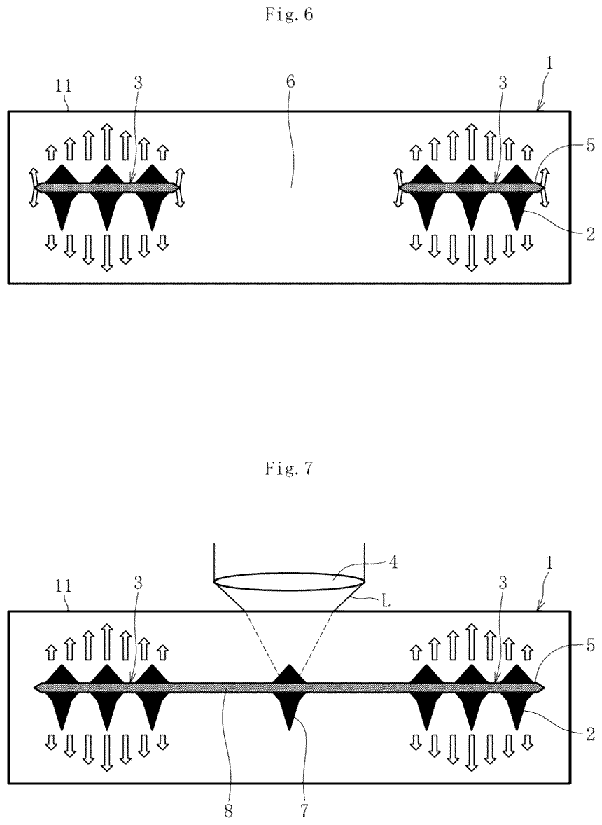

As shown in FIG. 4, the modified layer 3 described above is formed at a plurality of places inside the material 1 at intervals Q. The region having the interval Q is an unmodified region 6 that is not graphitized. Each modified layer 3 is disposed at the same depth from the surface 11, that is, on the same plane parallel to the (100) plane. At this time, the interval Q between the adjacent modified layers 3 is made larger than the pitch P between the first modified portions 2 included in the modified layer 3 (Q>P). As indicated by arrows in FIG. 6, stress in a direction to extend the crack acts on an edge portion of each modified layer 3, and the interval Q between the adjacent modified layers 3 is set such that the stress is slightly smaller than stress when the crack extends between the adjacent modified layers 3 and the cracks of both the modified layers 3 are joined.

If the interval Q between the modified layers 3 is too small, cracks of the adjacent modified layers 3 are connected to each other in a state where no external force is applied, and if the interval Q is too large, cracks are not connected to each other between the adjacent modified layers 3 even after formation of a second modified portion 7 to be described later, and it becomes difficult to peel off a thin plate having a large area. From the above viewpoint, the interval Q between the adjacent modified layers 3 is preferably larger than 30 μm and 1 mm or less. From the viewpoint of mass productivity and stability, the interval Q is more preferably larger than 50 μm and 100 μm or less.

Note that the number of the modified layers 3 formed inside the material 1 is arbitrary. Therefore, as shown in FIG. 4, in addition to forming the four modified layers 3 in one material 1, five or more modified layers 3 may be formed, or three or less modified layers 3 may be formed.

### Crack Joining Step

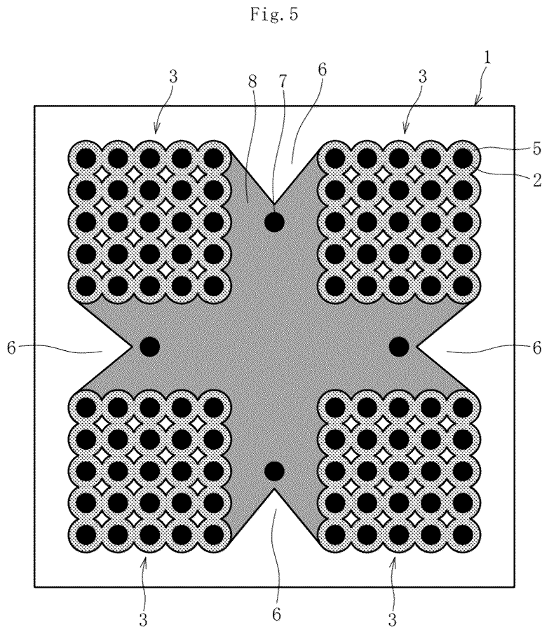

In the crack joining step, as illustrated in FIG. 5, the second modified portion 7 having a dot shape is newly formed at the unmodified region 6 between the adjacent modified layers 3, for example, at an intermediate position between the adjacent modified layers 3. A form and a forming method of the second modified portion 7 are the same as those of the first modified portion 2 formed in the modified layer 3. That is, the second modified portion 7 is formed by condensing the laser beam L at the same depth as a condensing position at the time of forming the first modified portion 2 and modifying (graphitizing) the material. A new crack existing region 8 is formed around the second modified portion 7 by volume expansion thereof.

When the second modified portion 7 is provided in the unmodified region 6 between the adjacent modified layers 3 in the stress accumulated state illustrated in FIG. 6, as illustrated in FIGS. 5 and 7, a new crack generated along with the formation of the second modified portion 7 serves as a trigger, and cracks of the adjacent modified layers 3 are connected in a chain manner via the new crack existing region 8. At this time, an entire region surrounded by a line connecting the adjacent second modified portions 7 is often a new crack existing region 8. Even if the number of (for example, one) second modified portions 7, which is smaller than the number (five in FIG. 5) of the first modified portions 2 of the other modified layer 3 facing the first modified portions 2 arranged at the edge of the one modified layer 3, of the adjacent modified layers 3, is formed, cracks can be connected between the adjacent modified layers 3. In FIG. 5, the second modified portions 7 are provided one by one in all the unmodified regions 6 sandwiched between the adjacent modified layers 3, but the number of second modified portions 7 provided in each of the unmodified regions 6 may be two or more. In addition, it is not necessary to provide the second modified portion 7 in all the unmodified regions 6 sandwiched between the adjacent modified layers 3 of the material 1, and the second modified portion 7 may be formed only in some of the unmodified regions 6.

### Peeling Step

By applying the external force to the material 1 (member made of crystal material) in which the plurality of modified layers 3 and the second modified portion 7 are formed in the above procedure, the crack generated in each modified layer 3 reaches an edge of the material 1, and as shown in FIG. 8, the thin plate 9 is separated from the material 1 using the plane including all the modified layers 3 as an interface. The external force can be applied, for example, by applying an impact to a side surface of the material 1. Thereafter, the modified layer 3 remaining on the peeled thin plate 9 is removed by polishing or the like, whereby a wafer can be obtained. The peeling step can be performed by etching in addition to applying the external force to the material 1 as described above.

In the existing slicing method as described in Patent Literature 1, since the extension of the crack α (see FIG. 2) in the cleavage plane direction cannot be avoided, it is difficult to peel off the thin plate 9 having a large area. However, in the slicing method of the present embodiment, the modified layer 3 having a small area to such an extent that the extension of the crack a in the cleavage plane direction does not occur is formed at the plurality of positions with the appropriate interval, and then the second modified portion 7 is newly formed between the adjacent modified layers 3 to extend the crack in a chain manner, and the thin plate 9 having a large area is peeled off. As a result, it is possible to slice the thin plate 9 having a large area, for example, the thin plate 9 having a size of 1 mm square or more, and further the thin plate 9 having an inch size from the material 1. This makes it possible to increase a diameter of the diamond wafer. Since thickness of the modified layer 3 is about 50 μm at the most, a cutting margin required for slicing is reduced, and the material 11 can be economically used. In addition, as compared with the slicing method described in Non-Patent Literature 1, a window can be expanded, and options of materials and devices can also be expanded.

Further, according to the present embodiment, the thin plate 9 can be peeled off in the direction along the (100) plane. While it is difficult to smooth the (111) plane by mechanical polishing which is a post-process, the (100) plane can be easily smoothed by polishing. Therefore, by peeling off the thin plate 9 in the direction along the (100) plane, there is an advantage that the thin plate 9 can be polished in the post-process and can be easily used as a wafer. A substrate having the (100) plane as a surface is most demanded as an application of a diamond single crystal including a semiconductor element and a semiconductor device, and the present invention has remarkable significance in that the area can be increased.

FIG. 9 shows another example of an arrangement pattern of the first modified portion 2 formed in the modified layer 3. In the embodiment shown in FIG. 9, the first modified portion 2 of the modified layer 3 includes a main modified portion 2a formed at a position aligned in each of a row direction X and a column direction Y of the modified layer 3 and a sub-modified portion 2b located between the main modified portions 2a adjacent in the row direction and between the main modified portions 2a adjacent in the column direction. With such an arrangement pattern of the first modified portions 2a and 2b, it is possible to further increase an area of each of the modified layers 3 while suppressing extension of the crack a in the cleavage plane direction. Therefore, it is possible to efficiently obtain the thin plate 9 having a larger area.

Note that, in the above embodiment, a case where the modified layer 3 is formed by condensing the laser beam inside the material 11 has been exemplified, but the method of forming the planar modified layer 3 is not limited thereto, and any method capable of forming the planar modified layer 3 can be adopted. For example, the planar modified layer 3 including a large number of the first modified portions 2 may be formed by graphitizing an ion beam by driving the ion beam into the material and embrittling an ion-implanted layer by annealing or etching. In this case, the material 1 can be sliced by irradiating a laser beam between the plurality of modified layers 3 located on the same plane to form the dot-shaped second modified portion 7.

In addition, diamond has been exemplified as the crystal material, but the slicing method described above can be widely used for slicing of crystal materials which are difficult to slice by a wire saw and have cleavability, for example, SiC, GaN, and sapphire.

### REFERENCE SIGNS LIST

1 Material
2 First modified portion
2a Main modified portion
2b Sub-modified portion
3 Modified layer
5 Crack existing region
7 Second modified portion
8 New crack existing region
9 Thin plate

1. A method for slicing a crystal material, the method comprising:
forming a planar modified layer including a first modified portion in a material made of a crystal material at a plurality of places on a same plane at intervals, the crystal material having cleavability;
subsequently forming a second modified portion between the modified layers adjacent to each other; and
joining cracks generated in the adjacent modified layers by forming the second modified portion, and peeling a thin plate from the material.

2. The method for slicing a crystal material according to claim 1, wherein the modified layer before forming the second modified portion has a size in which a crack in a cleavage plane direction does not extend.

3. The method for slicing a crystal material according to claim 1, wherein the interval between the adjacent modified layers before forming the second modified portion is set to a size in which cracks generated in the modified layers are not joined to each other.

4. The method for slicing a crystal material according to claim 1, wherein the crystal material is diamond, and the first modified portion and the second modified portion have a graphitized structure.

5. The method for slicing a crystal material according to claim 1, wherein the crystal material is diamond, and the modified layers formed at the plurality of places are arranged on the same plane parallel to a (100) plane.

6. The method for slicing a crystal material according to claim 1, wherein the first modified portion of the modified layer is formed at a position aligned in each of a row direction and a column direction of the modified layer.

7. The method for slicing a crystal material according to claim 1, wherein the first modified portion of the modified layer includes a main modified portion formed at a position aligned in each of a row direction and a column direction of the modified layer and a sub-modified portion located between the main modified portions adjacent in the row direction and between the main modified portions adjacent in the column direction.

8. A method for manufacturing a wafer, the method comprising forming a wafer by slicing the material by the method according to claim 1.

9. A member comprising a crystal material,
wherein a planar modified layer including a first modified portion is formed in a material made of a crystal material at a plurality of places on a same plane at intervals, and the crystal material has cleavability, and
a second modified portion is formed between the modified layers adjacent to each other.
